(19) United States
(12) Patent Application Publication
(10) Pub. No.: US 2012/0103794 A1
(43) Pub. Date: May 3, 2012

(54) METHOD OF COATING AN RF DEVICE AND SPUTTERING APPARATUS USED IN THE SAME

(75) Inventors: Myoung-Joon JUNG, Gyeonggi-Do (KR); Myoung-Ho KIM, Gwangju-si (KR); Hyun-Yeong JUNG, Gwangju-si (KR); Se-Young OH, Incheon-si (KR)

(73) Assignee: ACE TECHNOLOGIES CORPORATION, Incheon-si (KR)

(21) Appl. No.: 13/282,113

(22) Filed: Oct. 26, 2011

(30) Foreign Application Priority Data
Oct. 27, 2010 (KR) 10-2010-0105415

(51) Int. Cl. C23C 14/34; C25B 11/04; C25B 11/00

(52) U.S. Cl. 204/192.15; 204/192.12; 204/298.12; 204/298.13

(57) ABSTRACT

A method of coating an RF device for reducing cost of manufacture and coating period of time and a sputtering apparatus used in the same are disclosed. The sputtering apparatus used for coating of an RF device includes a supporting member on which an object to be coated corresponding to the RF device is placed, a first target made up of material coated on the object and a second target disposed separately from the first target. Here, power is applied to the first target and the second target when the object is coated.

### TECHNICAL FIELD

Example embodiment of the present invention relates to a method of coating an RF device using a dry method and a sputtering apparatus used in the same.

### BACKGROUND ART

An RF device is generally manufactured by coating material having excellent electric conductivity such as Ag, etc. on a base member so as to minimize its loss. In addition, coating for enhancing corrosion resistance may be further performed on the RF device.

Recently, a wet method has been used for coating the RF device. However, since the wet method uses a lot of additional material as well as coating material, and so cost for manufacture increases and much period of time is needed.

The above information disclosed in this Related Art section is only for enhancement of understanding of the background of the invention and therefore it may contain information that does not form the prior art that is already known in this country to a person of ordinary skill in the art.

### DISCLOSURE

### Technical Problem

Accordingly, the present invention is provided to substantially obviate one or more problems due to limitations and disadvantages of the related art.

An example embodiment of the present invention provides a method of coating an RF device for reducing cost of manufacture and coating period of time and a sputtering apparatus used in the same.

### Technical Solution

In one aspect, the present invention provides a sputtering apparatus used for coating of an RF device comprising: a supporting member on which an object to be coated corresponding to the RF device is placed; a first target made up of material coated on the object; and a second target disposed separately from the first target. Here, wherein power is applied to the first target and the second target when the object is coated.

In another aspect, the present invention provides a sputtering apparatus used for coating of a RF device comprising: a supporting member on which an object to be coated corresponding to the RF device is placed; and a target facing to the supporting member, and made up of material coated on the object. Here, at least one of the target and the object swings up and down during a coating process.

In still another aspect, the present invention provides a method of coating an RF device using a sputtering apparatus including a supporting member and a target, the method comprising: applying a first voltage to an object to be coated corresponding to the RF device through the supporting member and providing preset power to the target; and applying a second voltage to the object after predetermined period of time elapses from the applying of the first voltage.

### Advantageous Effects

A method of coating an RF device of the present invention as a dry method uses a sputtering apparatus, cost of manufacture and coating period of time may reduce. In addition, the method minimizes thickness difference of the RF device according to coated location through a method of using plural targets, a method of moving a target up and down or a method of moving an object to be coated up and down, and thus the RF device may have excellent electrical characteristics.

### BRIEF DESCRIPTION OF DRAWINGS

Example embodiments of the present invention will become more apparent by describing in detail example embodiments of the present invention with reference to the accompanying drawings, in which:

FIG. 1 is a view illustrating an RF device according to one example embodiment of the present invention;

FIG. 2 is a sectional view illustrating a sputtering apparatus and targets according to one example embodiment of the present invention;

FIG. 3 is a view illustrating common coating result;

FIG. 4 is view illustrating a process of coating the RF device according to a first embodiment of the present invention;

FIG. 5 is a view illustrating coating result according to the process in FIG. 4;

FIG. 6 is a sectional view illustrating schematically a process of coating the RF device according to a second embodiment of the present invention;

FIG. 7 is a sectional view illustrating schematically a process of coating the RF device according to a third embodiment of the present invention;

FIG. 8 is a sectional view illustrating schematically a process of coating a RF device according to a fourth embodiment of the present invention; and

FIG. 9 is a sectional view illustrating schematically a sputtering apparatus according to another embodiment of the present invention.

| | |
|---|---|
| 100: housing | 102: cavity |
| 104: resonator | 110: base member |
| 112: first conducting layer | 114: second conducting layer |
| 200: sputtering apparatus | 210: target |
| 212: supporting member | 214: object to be coated |
| 400: object to be coated | 600, 602: target |
| 604: object to be coated | 700: target |
| 702: object to be coated | 800: target |
| 802: object to be coated | 900: supporting member |
| 902: object to be coated | 904: electrode |

### BEST MODE FOR CARRYING OUT THE INVENTION

Hereinafter, embodiments of the present invention will be described in detail with reference to accompanying drawings.

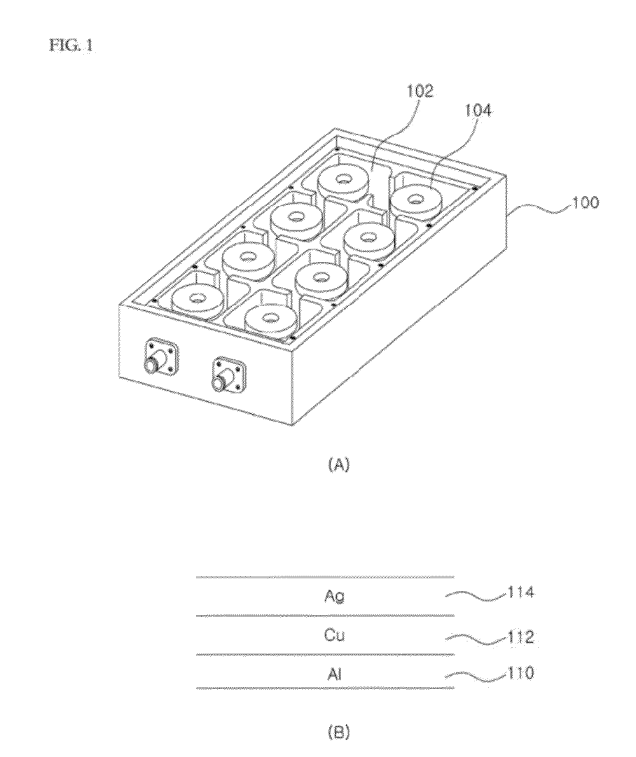

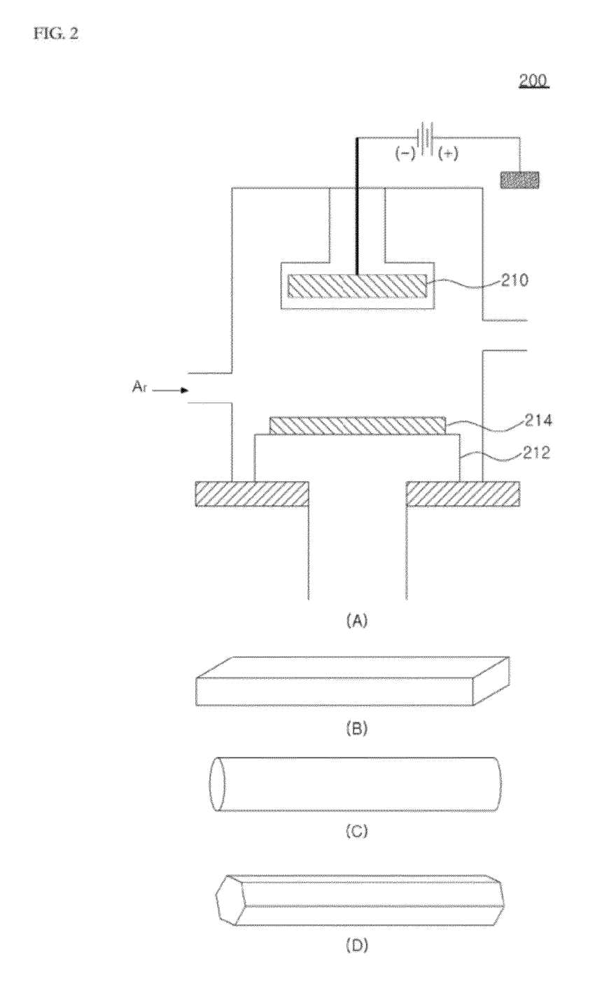

FIG. 1 is a view illustrating an RF device according to one example embodiment of the present invention, and FIG. 2 is a sectional view illustrating a sputtering apparatus and targets according to one example embodiment of the present invention.

In FIG. 1(A) and FIG. 2(A), an RF device may be a cavity filter having a housing 100, cavities 102 and resonators 104, and is coated through a dry method by using the sputtering apparatus 200. However, various RF devices as well as the cavity filter may be used as the RF device of the present invention as long as bottom surface and sides of the RF devices are coated. Hereinafter, the RF device will be assumed as the cavity filter for the purpose of convenience of description.

In the RF device in FIG. 1(B), a first coating layer 112 made up of copper Cu and a second coating layer 114 made up of silver Ag may be disposed in sequence on a base member 110 made up of aluminum Al.

In one embodiment of the present invention, the sputtering apparatus 200 forms the first coating layer 112 on the base member 110 and forms the second coating layer 114 on the first coating layer 112.

Hereinafter, a process of coating the RF device using the sputtering apparatus 200 will be described in detail.

In FIG. 2(A), the sputtering apparatus 200 includes a target 210, a supporting member 212 and an object 214 to be coated.

The target 210 is made up of material to be coated on the RF device, i.e. may be made up of first coating material Cu or second coating material Ag for the first coating layer 112.

In one embodiment of the present invention, the target 210 is fixed and does not move during a coating process (deposition process). A power is provided to the target 210 as shown in FIG. 2(A).

The target 210 may have rectangular parallelepiped shape as shown in FIG. 2(B), and have cylinder shape or polygon shape more than pentagon as shown in FIG. 2(C) and FIG. 2(D). In case that the target 210 has polygon shape more than pentagon, more much coating material may be coated on the side of the object 214 when the three-dimensional object 214 is coated.

The supporting member 212 supports the RF device 214. A bias voltage is applied to the object 214 through the supporting member 212.

The object 214 as a device to be coated indicates an RF device before the first coating layer 112 is formed or an RF device before the second coating layer 114 is formed. The object 214 is illustrated schematically in shown FIG. 2, but has the shape shown in FIG. 1(A).

Hereinafter, a process of coating the RF device using the sputtering apparatus 200 will be described in detail.

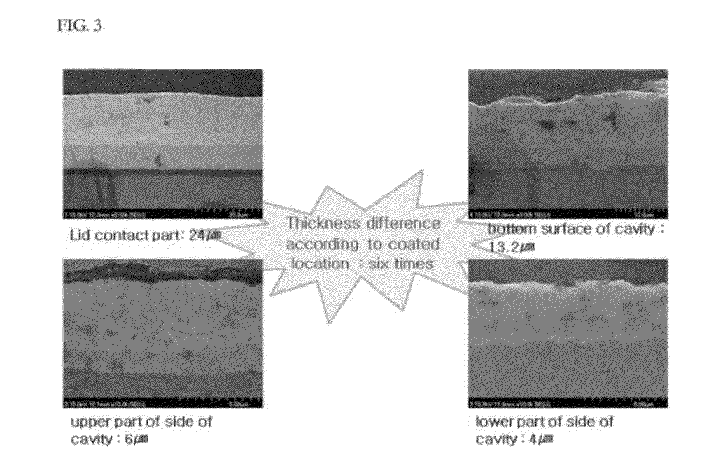

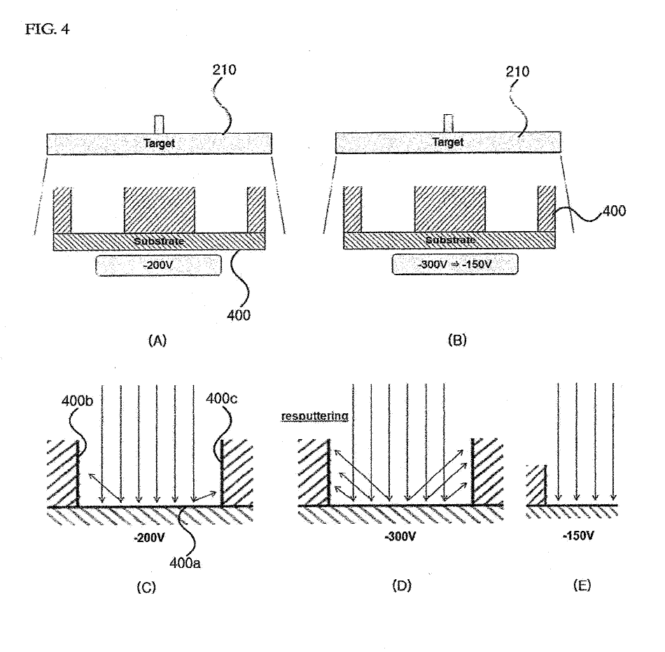

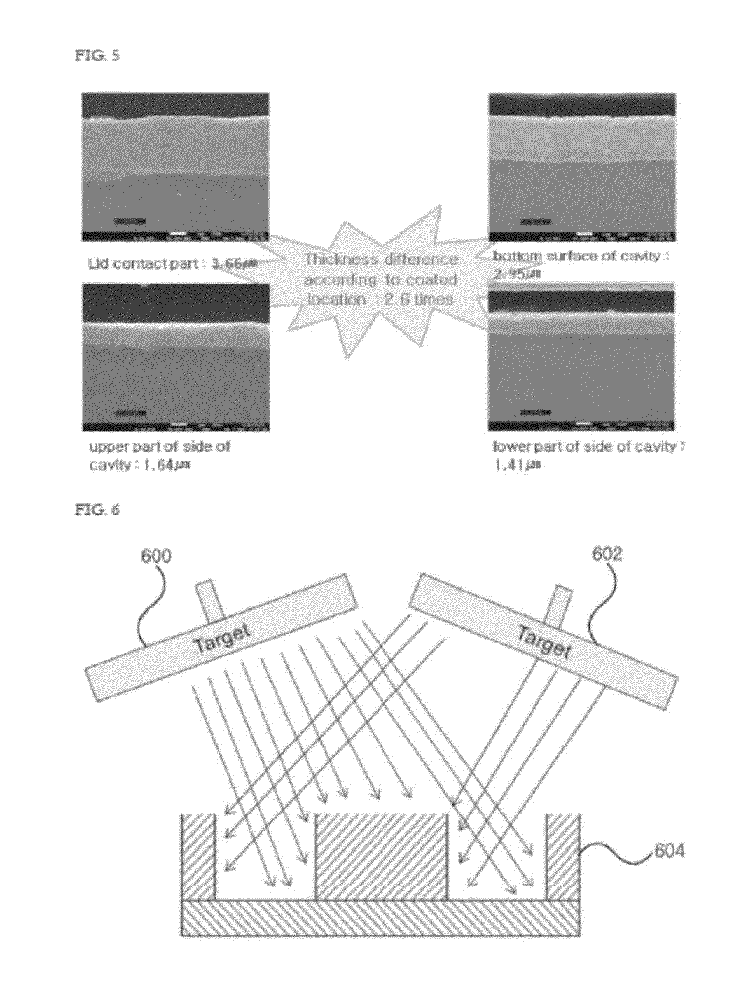

FIG. 3 is a view illustrating common coating result, FIG. 4 is view illustrating a process of coating the RF device according to a first embodiment of the present invention, and FIG. 5 is a view illustrating coating result according to the process in FIG. 4. FIG. 4 shows only one resonator and one cavity in the object 214, and the object is indicated with extra numerical number 400.

In FIG. 2 and FIG. 4, the target 210 is mounted to an upper part of a chamber in the sputtering apparatus 200, and the object 214 is placed on the supporting member 212.

Subsequently, atmosphere of the chamber changes into vacuum state by using a vacuum pump, and an inert gas, e.g. argon gas Ar is supplied into the chamber as shown in FIG. 2.

Then, the power is applied to the target 210, and preset bias voltage is provided to the object 214 through the supporting member 212. As a result, the argon gas Ar is glow-discharged, and so Ar+ ions are generated, i.e. the argon gas Ar is changed into plasma. Here, Ar+ ions collide with the target 210 (the collision may be activated by using magnetic force, which is not shown), and thus the target 210 is sputtered by the collision. That is, coating material splits from the target 210, and the coating material splitting from the target 210 is coated on the object 214.

In one embodiment of the present invention, the method of coating the RF device applies a first bias voltage, e.g. 300V at initial as shown in FIG. 4(B), and provides a second bias voltage, e.g. 150V lower than the first bias voltage after predetermined period of time lapses from the application of the first bias voltage. For example, the method applies the first bias voltage at initial, and changes the first bias voltage into the second bias voltage when half of total coating time elapses. In this case, the coating material is coated on a bottom surface 400a and sides 400b and 400c of the cavity 102. Particularly, much coating material is coated on the sides 400b and 400c in case that the first bias voltage is applied, and lots of coating material is coated on the bottom surface 400a in case that the second bias voltage is provided. As a result, the thickness difference of the RF device according to coated location may be maintained in thickness difference less than three times as shown in FIG. 5.

Thickness difference according to coated location affects to electrical characteristics of the RF device, e.g. electrical characteristics of the RF device is deteriorated in case that the thickness difference according to coated location is great. Accordingly, it is important to maintain the thickness difference according to coated location in small thickness difference rate, and thus the method of coating the RF device of the present invention maintains the thickness difference according to coated location in small thickness difference rate through change of the bias voltages, thereby enhancing the electrical characteristics of the RF device.

Hereinafter, experimental results concerning thickness difference in case of applying constantly a bias voltage during the coating process as shown in FIG. 4(A) and thickness difference in case of changing a bias voltage during the coating process as shown in FIG. 4(B) will be described in detail.

TABLE 1
in case of providing constantly the bias voltage

| Material of | Tempera- | | | | |
|---|---|---|---|---|---|
| a coating | ture in the | Pressure of | Supplying | Bias | |
| layer | chamber | the chamber | rate of gas | voltage | power |
| Cu | 200° C. | 5 m Torr | 30 sccm | −200 V | 200 W |
| Ag | 200° C. | 5 m Torr | 30 sccm | −200 V | 200 W |

TABLE 2
in case of changing the bias voltage

| Material of | Tempera- | | | | |
|---|---|---|---|---|---|
| a coating | ture in the | Pressure of | Supplying | Bias | |
| layer | chamber | the chamber | rate of gas | voltage | power |
| Cu | 200° C. | 5 m Torr | 30 sccm | −300 V → | 200 W |
| | | | | −150 V | |
| Ag | 200° C. | 5 m Torr | 30 sccm | −200 V → | 200 W |
| | | | | −150 V | |

In case of performing the coating process under the condition that the bias voltage is maintained during the coating process as shown in Table. 1, the thickness difference of the object 400 according to coated location occurs by maximal 6 times thickness difference as shown in FIG. 3. As a result, electrical characteristics of the RF device manufactured through the coating process may be deteriorated.

In case of changing the bias voltage during the coating process as shown in Table 2, the thickness difference of the object 400 according to coated location occurs by maximal 2.6 times thickness difference as shown in FIG. 5. In other words, the thickness difference according to coated location may be less than three times thickness difference, and so the RF device manufactured through the coating process may have excellent electrical characteristics.

In brief, the method of coating the RF device of the present invention coats the first conducting layer 112 or the second conducting layer 114 using the sputtering device 20, i.e. performs the dry coating. Specially, the method maintains the thickness difference according to coated location in thickness difference less than three times by changing the bias voltage during the coating process.

In case that the RF device is manufactured through a wet method, the RF device according to coated location may be less than three times. However, since the wet method uses much additional material as well as coating material, manufacture cost and coating time of the RF device increase.

However, in case that the RF device is manufactured through the dry method using the sputtering apparatus 200, the thickness difference of the RF device according to coated location is less than three times and additional material is not nearly needed. Accordingly, manufacture cost of the RF device reduces by 80% compared with in the wet method and coating time decreases.

FIG. 6 is a sectional view illustrating schematically a process of coating the RF device according to a second embodiment of the present invention.

In FIG. 6, at least two targets 600 and 602 are used in a sputtering apparatus used in the method of coating the RF device of the present embodiment.

The first target 600 is disposed in e.g. “/” direction, and the second target 602 is placed in “\” direction. The targets 600 and 602 are made up of the same material, e.g. Cu or Ag, and the same power may be simultaneously provided to the targets 600 and 602 during a coating process.

In case that the targets 600 and 602 are placed as shown in FIG. 6, the coating material may be coated on the sides of the RF device. Generally, amount of the coating material coated on the bottom surface of the RF device is higher than that of coating material coated on the sides of the RF device. However, amount of the coating material coated on the sides of the object 604 increases by placing the targets 600 and 602 as shown in FIG. 6, and so the thickness difference between the bottom surface and the sides may reduce. As a result, the method of coating the RF device may maintain the thickness difference according to coated location in thickness difference less than three times by placing the targets 600 and 602 as shown in FIG. 6.

In another embodiment of the present invention, the method of coating the RF device may further include a process of changing the bias voltage during the coating process like the first embodiment.

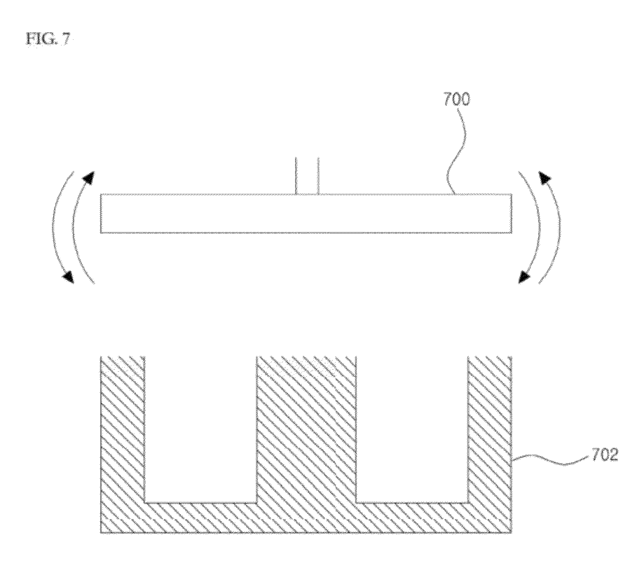

FIG. 7 is a sectional view illustrating schematically a process of coating the RF device according to a third embodiment of the present invention.

In FIG. 7, a sputtering apparatus used in a method of coating the RF device of the present embodiment has one target 700, and the target 700 moves up and down, in particularly both ends of the target 700 swing up and down. As a result, amount of coating material coated on sides of the object 702 to be coated increases, and so thickness difference between a bottom surface and the sides may reduce. Accordingly, the method of coating the RF device of the present embodiment may maintain the thickness difference according to coated location in thickness difference less than three times.

In another embodiment of the present invention, the method of coating the RF device may further include a process of changing a bias voltage during a coating process like the first embodiment.

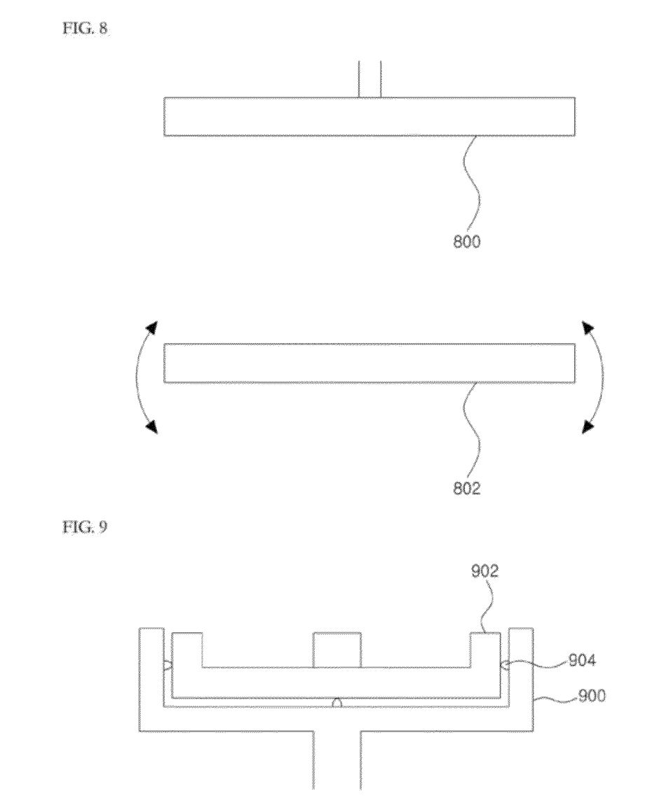

FIG. 8 is a sectional view illustrating schematically a process of coating a RF device according to a fourth embodiment of the present invention.

In FIG. 8, a target 800 of a sputtering apparatus used in the method of coating the RF device of the present embodiment is fixed, and an object 802 to be coated moves (swings) up and down. Preferably, a supporting member swings the object 802. As a result, amount of coating material coated on sides of the object 802 to be coated increases, and so thickness difference between a bottom surface and the sides may reduce. Accordingly, the method of coating the RF device of the present embodiment may maintain the thickness difference according to coated location in thickness difference less than three times.

In another embodiment of the present invention, the method of coating the RF device may further include a process of changing a bias voltage during a coating process like the first embodiment.

The methods of coating the RF device of the present invention may guarantee adhesion of the coating layer by performing a cleaning process for above 40 minutes, which is not described in the above embodiments.

FIG. 9 is a sectional view illustrating schematically a sputtering apparatus according to another embodiment of the present invention. FIG. 9 shows only a supporting member 900 and an object 902 to be coated of elements in the sputtering apparatus.

In FIG. 9, the supporting member 900 of the present embodiment has shape corresponding to shape of the object 902. That is, the supporting member 900 further includes bending part corresponding to side of the object 902.

In one embodiment of the present invention, at least one electrode 904 is formed on the supporting member 900. Preferably, the electrodes 904 are formed on the bending parts of the supporting member 900, i.e. parts corresponding to side of the object 902. A power is supplied to the object 902 through the electrodes 904. A method of supplying the power to the electrodes 904 is not limited, but may be variously modified.

In case that the electrodes 904 are formed on the parts corresponding to sides of the object 902, more much coating material may be coated on the side of the object 902.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A sputtering apparatus used for coating of an RF device comprising:
a supporting member on which an object to be coated corresponding to the RF device is placed;
a first target made up of material coated on the object; and
a second target disposed separately from the first target,
wherein power is applied to the first target and the second target when the object is coated.

2. The sputtering apparatus of claim 1, wherein the first target is disposed in “/” direction on the basis of normal of the RF device, and the second target is disposed in “\” direction on the basis of the normal of the RF device.

3. The sputtering apparatus of claim 1, wherein the RF device is a cavity filter, coating material splitting from the target is coated on a bottom surface and sides of a cavity, and maximal thickness difference of the bottom surface and the sides is less than three times.

4. The sputtering apparatus of claim 1, wherein the targets are made up of the same material, and the material is silver or copper.

5. The sputtering apparatus of claim 1, wherein a bias voltage applied to the object is changed during a coating process.

6. The sputtering apparatus of claim 1, wherein at least one of the first target and the second target has cylinder shape or polygon shape more than pentagon.

7. The sputtering apparatus of claim 1, wherein the supporting member includes a bending part corresponding to side of the object,
and wherein at least one electrode is formed on the bending part, and a power is provided to the object through the electrode.

8. A sputtering apparatus used for coating of a RF device comprising:
a supporting member on which an object to be coated corresponding to the RF device is placed; and
a target facing to the supporting member, and made up of material coated on the object,
wherein at least one of the target and the object swings up and down during a coating process.

9. The sputtering apparatus of claim 8, wherein the RF device is a cavity filter, coating material splitting from the target is coated on a bottom surface and sides of a cavity, maximal thickness difference of the bottom surface and the sides is less than three times, and the target is made up of silver or copper.

10. The sputtering apparatus of claim 8, wherein a bias voltage applied to the object is changed during the coating process.

11. The sputtering apparatus of claim 8, wherein the target has cylinder shape or polygon shape more than pentagon.

12. The sputtering apparatus of claim 8, wherein the supporting member includes a bending part corresponding to side of the object,
and wherein at least one electrode is formed on the bending part, and a power is provided to the object through the electrode.

13. A method of coating an RF device using a sputtering apparatus including a supporting member and a target, the method comprising:
applying a first voltage to an object to be coated corresponding to the RF device through the supporting member and providing preset power to the target; and
applying a second voltage to the object after predetermined period of time elapses from the applying of the first voltage.

14. The method of claim 13, wherein the second voltage is smaller than the first voltage, the first voltage is applied to the object during half of total coating time, and the second voltage is provided to the object during the other coating time.

15. The method of claim 14, wherein the RF device is a cavity filter, coating material splitting from the target is coated on a bottom surface and sides of a cavity, maximal thickness difference of the bottom surface and the sides is less than three times, the target is made up of silver or copper, and the target has cylinder shape or polygon shape more than pentagon.

16. The method of claim 13, wherein the sputtering apparatus has plural targets, and the same power is applied to the targets.

17. The method of claim 13, wherein the target or the object swings up and down, and the supporting member includes a bending part corresponding to side of the object,
and wherein at least one electrode is formed on the bending part, and a power is provided to the object through the electrode.
